(19) United States
(12) Patent Application Publication
(10) Pub. No.: US 2025/0046642 A1
(43) Pub. Date: Feb. 6, 2025

(54) CONFIGURABLE CHUCK AND RING APPARATUS

(71) Applicant: Core Flow Ltd., Daliyat el-Karmel (IL)

(72) Inventors: Alon SEGAL, Kiriyat Tivon (IL); Oshri Ifergan, Daliyat el-Carmel (IL); Yaron Baron, Daliyat el-Carmel (IL); Ronen Lautman, Haifa (IL); Sliman Nasereldeen, Daliyat el-Karmel (IL)

(73) Assignee: Core Flow Ltd., Daliyat el-Karmel (IL)

(21) Appl. No.: 18/793,951

(22) Filed: Aug. 5, 2024

Related U.S. Application Data
(60) Provisional application No. 63/530,970, filed on Aug. 5, 2023.

(51) Int. Cl. H01L 21/683

(52) U.S. Cl. CPC H01L 21/6838

(57) ABSTRACT

A chuck and a method for chemical and mechanical planarization processing that provides different pressure levels at different radii of the chuck's bottom surface. The chuck may include a vacuum ring that keeps a workpiece attached to the chuck bottom surface without touching it and a chuck ring that cooperates with the chuck for removing excess material during processing.

### CROSS-REFERENCE TO RELATED APPLICATIONS

The present application claims the benefit of U.S. Provisional Patent Application No. 63/530,970, filed on Aug. 5, 2023, which is incorporated by reference herein in its entirety.

### FIELD OF THE INVENTION

The present invention relates to chucks. More specifically, the present invention relates to a configurable chuck designed for use in a chemical and mechanical polishing/planarization (CMP) process and to a cooperating ring.

### BACKGROUND OF THE INVENTION

CMP is a process for smoothing surfaces by a combination of chemical and mechanical (or abrasive) actions to achieve highly smooth and planar material surfaces, and is used in different technologies and configurations. For example, CMP is used for polishing wafers in the semiconductor field of technology, where a chuck is placed in contact with a wafer and rotates over it, applying chemical and mechanical abrasion and smoothing of the surface of that wafer. The quality of the CMP process depends on the mechanical contact between the chuck and the wafer. Furthermore, it is sometime desired to apply different levels of pressure across the wafer and modulate these different levels of pressure, to enhance the CMP process.

For example, some processes require a stronger push at the center of the wafer. Other processes require a stronger push at the rim of the wafer. Some processes require up to five independent zones where the push must be controlled. A single tool may be configured by a technician by removing the chuck and replacing some of its parts before reassembling the chuck into the tool in preparation for a process. This configuration is time-consuming and causes wear on the mechanical parts.

Other technologies exist for supporting workpieces in wet processes. They may include mechanical contact between the workpiece and a chuck. The chuck may be configurable by adding or removing metal or ceramic segments of the chuck in preparation for each process which entails interruptions in the CMP process, tedious handling and wear on parts of the chuck.

It is an objective of the present invention to provide a configurable chuck for use in CMP processes that offers the ability to apply and modulate different pressure levels across the processed wafer.

### SUMMARY OF THE INVENTION

There is thus provided, in accordance with embodiments of the present invention, a chuck for chemical and mechanical planarization processing.

An embodiment of the current invention allows gas flow through the chuck. Gas may flow from a pressure source, through a supply system to the chuck. The interior of the chuck may allow for the distribution of the gas to the surface of the chuck that may be proximal to the workpiece via ports. The gas may flow between the surface of the chuck and the workpiece until it reaches the ambient pressure. The chuck may be configurable; for one process the chuck may distribute more gas to the center of the chuck, and for another process the chuck may distribute more gas to the rim of the chuck, and for another process the chuck may distribute more gas to an intermediate location between the center and the rim. The configuration may be done manually or automatically, as the chuck may be prepared to handle one process or another. The configuration may be done with the chuck mounted to the tool, thus saving time in disassembly and reassembly of the same.

The gas separating the chuck surface from the workpiece may reduce the friction acting on a workpiece in the wetted area. An embodiment of the current invention includes a contact area between the surface of the chuck and the workpiece. The contact area may be found by the exclusion zone of the workpiece as determined by the processing done on the workpiece.

An embodiment may apply gas at configurable flowrates to the workpiece, thus reducing the wear on the mechanical parts of the chuck. Furthermore, the configuration may take less time, allowing for less downtime in between processes.

The chuck may include a body with substantially flat bottom surface having a plurality of pressure nozzles distributed across the bottom surface. The chuck may include one or more pressure input ports for connecting to a pressure source, for providing pressurized air or gas. The chuck may include internal passages, configured to deliver the pressurized air or gas to the plurality of pressure nozzles, and to apply pressure through the plurality of pressure nozzles onto a workpiece in a concentric manner. The chuck may include different pressure levels at different concentric strips of the plurality of pressure nozzles.

In some embodiments, the chuck may include one or more vacuum input ports for connecting to a vacuum source. The chuck may include one or more input ports for connecting to a vacuum source. The chuck may include a plurality of vacuum nozzles at the bottom of the chuck, along a concentric circle surrounding the pressure nozzles. The chuck may include internal passages, configured to deliver the vacuum to the plurality of vacuum nozzles, and to apply vacuum through the plurality of vacuum nozzles on a workpiece to keep a workpiece attached to the bottom of the chuck during processing.

In some embodiments, the chuck may include a plurality of evacuation channels in the chuck body for the pressurized air or gas.

In some embodiments, the chuck may include a concentric vacuum ring surrounding the plurality of vacuum nozzles and configured to keep a distance between the bottom of the chuck and a workpiece.

In some embodiments, the chuck may include a plurality of segmented vacuum rings surrounding the plurality of vacuum nozzles and configured to keep a distance between the bottom of the chuck and a workpiece and to allow evacuation of pressurized air or gas outward of the chuck in between the plurality of segmented vacuum rings.

In some embodiments, the body of the chuck is round or circular.

In some embodiments, one or more of the pressure input ports of the chuck is connected to a pressure source via a manually or automatically controlled needle valve.

In some embodiments, two or more of the pressure input ports of the chuck are connected to a pressure source via a manually or automatically controlled common pressure valve.

In some embodiments, one or more of the pressure input ports of the chuck is connected to a pressure source via a pressure regulator.

In some embodiments, the chuck includes one or more pressure sensors, configured to measure the pressure of the one or more pressure input ports of the chuck.

In some embodiments, the chuck includes one or more distance sensors, configured to measure the distance between the bottom of the chuck and the top of a workpiece and the thickness of a workpiece.

In one aspect, the invention includes a chuck ring for removing excess material outward of a chuck during processing. The chuck ring may include a ring inside which a chuck may fit snugly. The chuck ring may include a plurality of pressure nozzles distributed around the chuck ring. The chuck ring may include a plurality of pressure input ports for connecting to a pressure source, for providing pressurized air or gas to the plurality of pressure nozzles. The chuck ring may include a plurality of flow restrictors on top of the chuck ring, each connected to a pressure source and to one of the plurality of pressure input ports. The chuck ring may include a plurality of channels at the bottom of chuck ring for evacuating pressurized air or gas and excess material outward from the chuck ring.

One embodiment includes a method for chemical and mechanical planarization processing. One or more vacuum ports may connect to a vacuum source, for providing vacuum to the chuck. The vacuum may be delivered through internal passages to a plurality of vacuum nozzles at the bottom of the chuck along a concentric circle surrounding a plurality of pressure nozzles distributed across the bottom surface of the chuck. The vacuum may be applied through the plurality of vacuum nozzles on a workpiece to keep a workpiece attached to the bottom of the chuck during processing. A vacuum ring surrounding the plurality of vacuum nozzles may keep a workpiece from touching the bottom surface of the chuck. One or more pressure input ports of the chuck may connect to a pressure source, for providing pressurized air or gas to the chuck. The pressurized air or gas may be delivered through internal passages of the chuck to the plurality of pressure nozzles. The pressurized air or gas may apply different pressure levels at different concentric strips of the plurality of pressure nozzles. The pressurized air or gas may be evacuated through a plurality of evacuation channels in the body of the chuck.

In some embodiments, the method includes keeping a workpiece from touching the bottom surface of the chuck by a plurality of segmented vacuum rings surrounding the plurality of vacuum nozzles.

In some embodiments, the method includes evacuating the pressurized air or gas through a plurality of channels between the plurality of segmented vacuum rings.

In some embodiments, the method includes connecting one or more of the pressure input ports of the chuck to a pressure source via a manually or automatically controlled needle valve

In some embodiments, the method includes connecting two or more of the pressure input ports of the chuck to a pressure source via a manually or automatically controlled common pressure valve.

In some embodiments, the method includes connecting one or more of the pressure input ports of the chuck to a pressure source via a pressure regulator.

In some embodiments, the method includes measuring the pressure of one or more of the pressure input ports of the chuck via a pressure sensor on the top of the chuck.

In some embodiments, the method includes measuring the distance between the bottom surface of the chuck and the top of a workpiece and the thickness of a workpiece, via distance sensors on top of the chuck.

In one aspect, the invention includes a method for removing excess material from a workpiece. A chuck ring may be fitted snuggly around a chuck. A plurality of pressure input ports of the chuck ring may connect to a pressure source for providing pressurized air or gas to the chuck ring. The pressurized air or gas may be delivered to a plurality of pressure nozzles distributed around the chuck ring. The pressurized air or gas and excess material may be evacuated outward of the chuck ring through a plurality of channels in the bottom surface of the chuck ring.

### BRIEF DESCRIPTION OF THE DRAWINGS

In order for the present invention to be better understood and for its practical applications to be appreciated, the following Figures are provided and referenced hereafter. It should be noted that the Figures are given as examples only and in no way limit the scope of the invention. Like components are denoted by like reference numerals.

FIG. 1 is an isometric view of a configurable chuck, according to some embodiments of the invention, showing the top surface of the chuck, with connected accessories.

FIG. 2 is a view of a bottom surface of a configurable chuck, according to some embodiments of the invention.

FIG. 3 is a view of an alternative design for a bottom surface of a configurable chuck, according to some embodiments of the invention.

FIG. 4 is a partial oblique view of a cross section of a body of a configurable chuck, according to some embodiments of the invention.

FIG. 5 shows a cross section of a configurable chuck, according to some embodiments of the invention, showing the top surface of the chuck, with connected accessories.

FIG. 6 is an oblique view of the top of a chuck ring for cooperation with a configurable chuck, according to some embodiments of the invention.

FIG. 7 is an oblique bottom view of the chuck ring shown in FIG. 6, according to some embodiments of the invention.

FIG. 8 is an oblique view of an alternative design for the bottom of a chuck ring, for cooperation with a configurable chuck, according to some embodiments of the invention.

FIG. 9 is an oblique view of a configurable chuck and a chuck ring, according to some embodiments of the invention.

FIG. 10 is a flow chart description of a method for chemical and mechanical planarization processing, according to some embodiments of the invention.

FIG. 11 is a flow chart description of a method for removal of excess material outward of a chuck, according to some embodiments of the invention.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, modules, units and/or circuits have not been described in detail so as not to obscure the invention.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. Unless explicitly stated, the method embodiments described herein are not constrained to a particular order or sequence. Additionally, some of the described method embodiments or elements thereof may occur or be performed simultaneously, at the same point in time, or concurrently. Unless otherwise indicated, the conjunction “or” as used herein is to be understood as inclusive (any or all of the stated options).

Aspects of the present invention relate to a configurable chuck for use in CMP. To address a need for applying different pressure forces over different sectors of the processed workpiece (e.g., wafer), during the CMP process, and modify these different pressures in various stages of the CMP process, a configurable chuck is hereby proposed.

According to some embodiments of the present invention, a configurable chuck for CMP uses may include a plurality of pressure ports distributed across a bottom surface of the chuck for exerting pressure forces onto the top of a workpiece (e.g., wafer), by applying air or other gas (hereinafter “air”, for brevity) pressure, for example, by using a pressure source, such as a pump, to provide pressurized air. According to some embodiments of the present invention, the pressure ports are arranged in concentric annular strips, each of the annular strips separately controlled, to allow independently applying different pressure forces at each or some of the concentric annular strips separately with respect to the other concentric annular strips, and to independently modify the flowrate through, and consequently the pressure exerted on each of the concentric annular strips.

According to some embodiments of the present invention, in order to facilitate evacuation of excess air from the top surface of the workpiece, during processing, evacuation channels for the air to escape into the ambient environment are provided. Such evacuation channels may have various designs, such as the ones described hereinafter and shown in the figures (and other suitable designs).

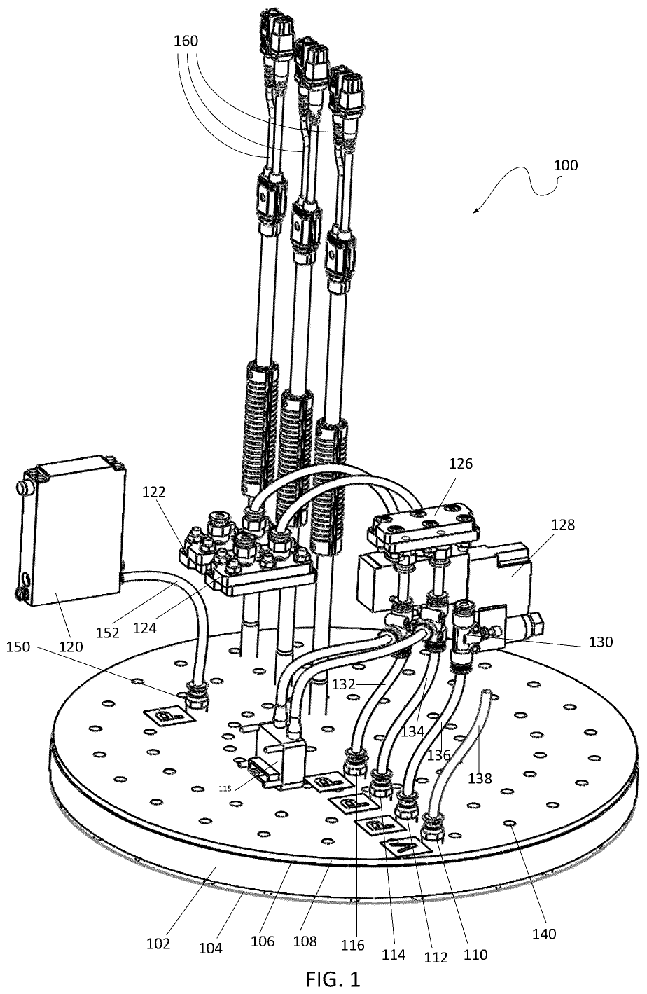

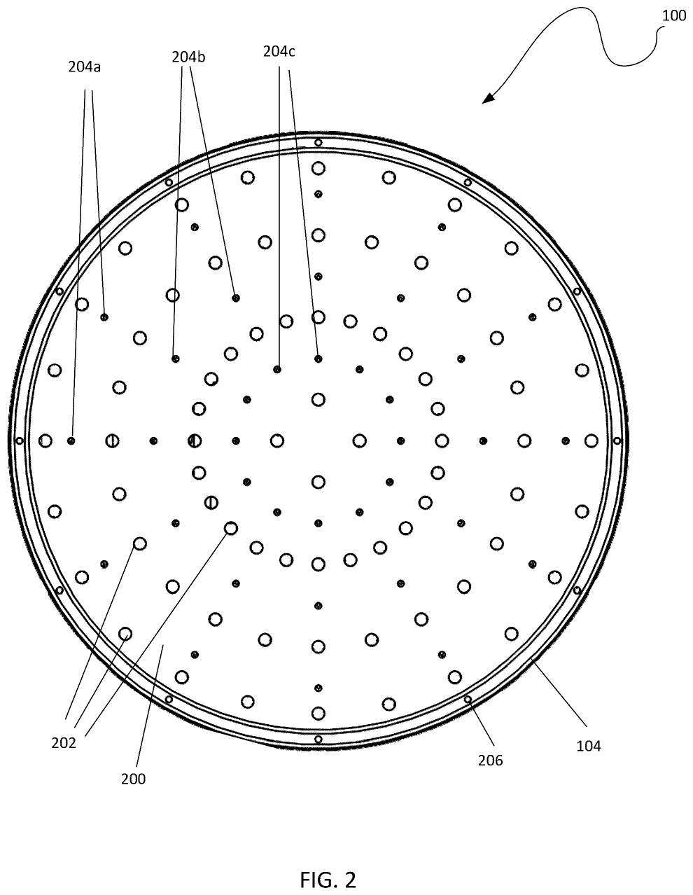

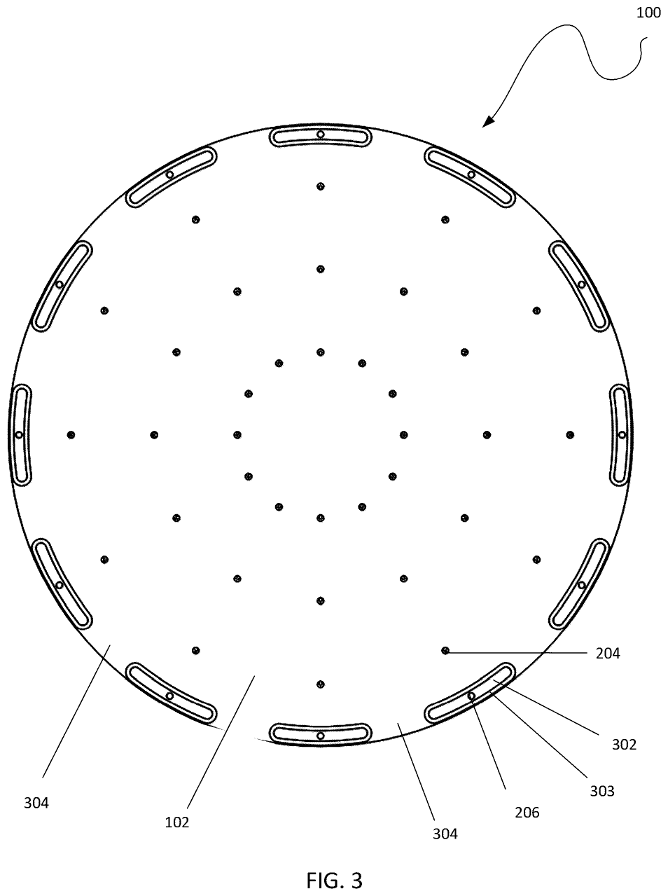

FIG. 1 is an isometric view of a configurable chuck, according to some embodiments of the invention, showing the top surface of the chuck, with connected accessories. Chuck 100 may be designed in the form of a substantially round or circular disk with a substantially flat bottom surface, which may suit rotational operation. Top cover plate 108 may include several ports (112, 114, 116) for connecting to a pressure source (not shown in the figures), via piping (132, 134, 136 respectively), each port (marked in FIG. 1 by “P”) for providing pressurized air into one of separate spaces within chuck 100 delimited by annular strip, of a plurality of concentric annular strips, that are located at the bottom surface of chuck 100 (see, for example, FIG. 2 and FIG. 3), so as to generate pressure forces through pressure nozzles distributed across a specific concentric annular strips of the plurality of concentric annular strips.

A vacuum port 110 may be provided (marked by “V” in FIG. 1), to facilitate connection to a vacuum source (not shown in the figures) for applying a suction force onto the workpiece through designated vacuum nozzles distributed at the bottom surface of the chuck.

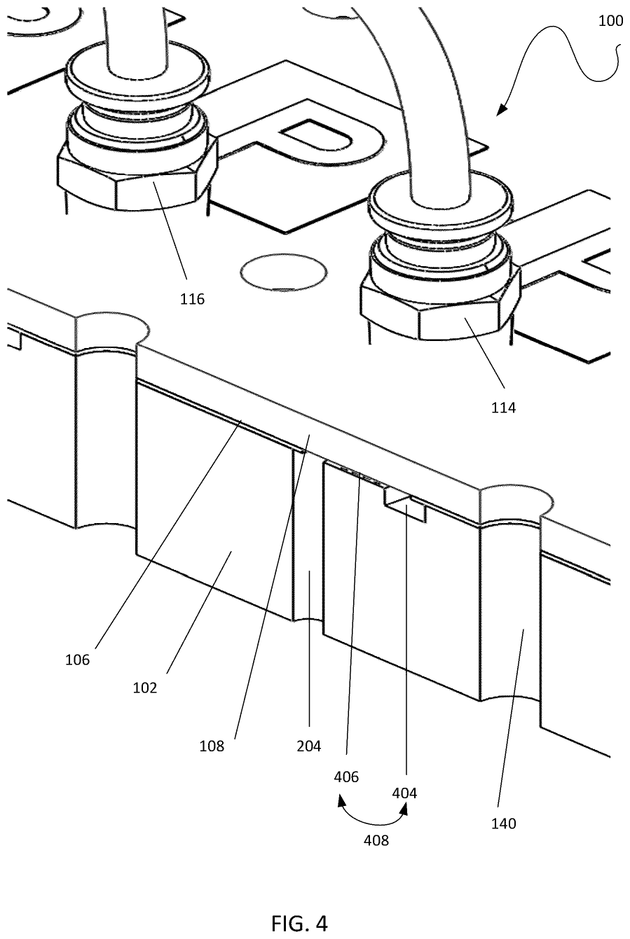

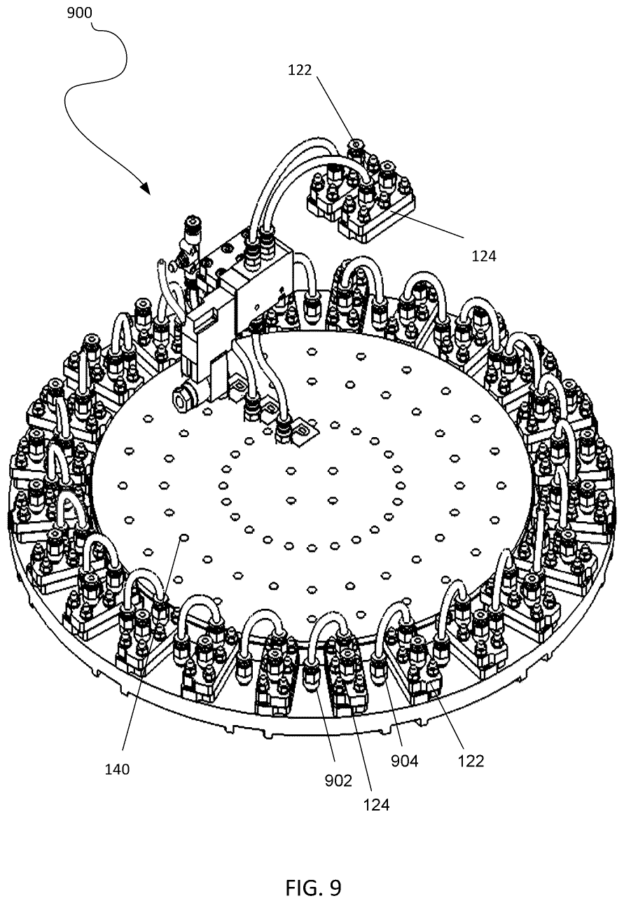

Evacuation outlets 140 of evacuation channels that are configured to facilitate evacuation of excess air over the workpiece caused by the flow through the pressure nozzles to the ambience (see also cross section in FIG. 4). Vacuum tube 138 may connect vacuum port 110 to a vacuum source (not shown). Pressure tube 136 may connect pressure port 112 to a pressure source (not shown), for example, through needle valve 130 (such as model no JNU6 by Pisco). Needle valve 130 may be adjusted manually to set the desired pressure at the pressure nozzles on the outer strip of the concentric annular strips. Pressure tubes 132 and 134 may connect pressure ports 116 and 114, respectively, to a pressure source (not shown) through a common pressure valve 128 (such as model no. SYJ312-6G-M3 by SMC). Different pressure levels may be obtained in pressure tubes 132 and 134 by, for example, pre-set flow resistors 126, which may include separate flow resistors for separate pressure tubes, 132 and 134; other methods of providing different pressure levels may be used. Each of pressure tubes 132 and 134 may be connected to a different strip of pressure nozzles that are arranged in concentric annular strips (see FIGS. 2 and 3). Pressure levels in pressure tubes 132 and 134 may be measured, for example, by a pressure sensor 118 (such as model no. PSE300 by SMC) which may be used to control pressure valve 128 (actual circuitry is not shown here for brevity). Pressure tube 152 may connect pressure input port 150 to a pressure source (not shown) through pressure regulator 120 (such as model no. IR1000-01A by SMC). Pressure tube 152 may supply pressurized air to a specific annular strip of pressure nozzles (not shown in this figure). Pressure regulator 120 may connect to a pressure source (not shown) to keep a pre-dialed pressure in pressure tube 152. Pre-set flow restrictor 122 may be connected to pressure valve 128 and to a chuck ring (not shown, see FIG. 9). Pressure valve 128 may be configured to be controlled by a controller. Pressure valve 128, as shown in FIG. 1, may connect any one of a selection of two flow restrictors (122 and 124) to the chuck. In some embodiments of the invention, pressure valve 128 may include a selection of more than two flow restrictors.

Distance sensors 160 (such as model no. GT2-P12 by Keyence) may be configured to measure the distance between the bottom of the chuck and the top of a workpiece and the thickness of a workpiece. These measurements may be used in figuring out the desired pressure levels fed to pressure input ports 112, 114, 116, and 150.

FIG. 2 shows a bottom surface of a configurable chuck, according to some embodiments of the invention. Pressure nozzles 204 in chuck 100 may be distributed across bottom surface 200 of chuck 100 in concentric strips, so that, in this example, pressure nozzles 204a are distributed over the outermost annular strap of a plurality of concentric annular strips, pressure nozzles 204b are distributed over the next inner annular strip, and pressure nozzles 204c are distributed over an innermost annular strip. The number of concentric annular strips may be determined based on the anticipated or desired performance of the configurable chuck. Each strip may be fluidically connected via a pressure port to a different pressure tube connected at the top surface of cover plate 108 of the chuck (see FIG. 1). The pressure nozzles of each strip may be configured to exert a different flowrate on a workpiece in a concentric manner by applying pressurized air at different pressure levels. Evacuation channels 202 may be distributed across the chuck body 102, for example over concentric annular strips positioned in between adjacent annular strips of pressure nozzles. Evacuation channels 202 may evacuate the pressurized air to be expelled out of evacuation outlets 140 on the top cover 108 of the chuck (see FIG. 1) and into the ambient environment. Vacuum nozzles 206 may be, for example, distributed across a vacuum ring 104. Vacuum ring may be placed, for example, on the outermost edge of bottom surface 200, or at any other location that allows a good vacuum grip to hold the workpiece to the bottom surface 200 of the chuck 100, and that does not adversely impact the processing. Vacuum nozzles 206 may be fluidically linked to a vacuum tube connected to a vacuum port at the top of the chuck (not shown, see FIG. 1). Vacuum nozzles 206 may hold a workpiece in direct contact to the bottom surface of the chuck during processing. Vacuum ring 104, for example, may be located at the edge of the bottom surface of the chuck so as to prevent direct contact between the workpiece and the body of the chuck 102 in order to prevent any damage that may incur on the workpiece by the body of the chuck 102.

FIG. 3 shows an alternative design for the bottom surface of a configurable chuck, according to some embodiments of the invention. Vacuum segments 302 that form a truncated ring about the edge of the bottom surface of the chuck 100 may effectively hold a workpiece. The vacuum segments may include raised rim 303, defining a sealed segment in which a vacuum port 206 is located. Evacuation of excess pressurized air may be achieved through gaps 304 between vacuum segments 302.

FIG. 4 is a partial oblique view of a cross section of a body of a configurable chuck, according to some embodiments of the invention. Chuck 100 includes pressure ports 114 and 116 at the top of the cover plate 108 that may be each connected via a tube to a pressure source, so as to provide pressurized air to pressure nozzles on different concentric annular strips (one pressure nozzle 204 is shown). Nozzle plate 106 may be set between cover plate 108 and chuck body 102. Nozzle plate 106 may include air passages that are configured to allow pressurized air or gas pass from pressure ports on top of the chuck (pressure ports 114 and 116 shown here) to pressure nozzles (pressure nozzle 204 shown here) through flow resistors 406 (such as, for example, self-adaptive segmented orifices—SASO, such as described in U.S. Pat. No. 7,530,778, incorporated herein by reference). Pressurized air may flow from pressure port 114 and may be distributed to pressure nozzles 204 via internal passages 408, which may include concentric channel 404 and flow resistors 406. Pressure port 114 and concentric channel 404 may be fluidically connected. Evacuation channel 140 may evacuate pressurized air from underneath the chuck body 102 to the top of the chuck and into the ambient environment.

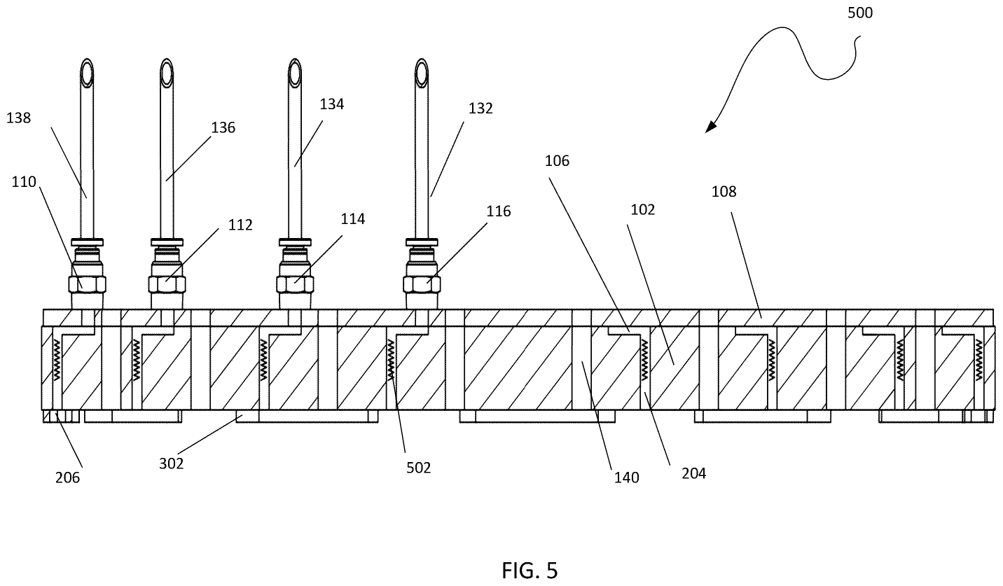

FIG. 5 is a side view of a cross section of a configurable chuck, according to some embodiments of the invention, showing the top surface of the chuck, with connected accessories. Vacuum tube 138 in chuck 500 may connect to vacuum port 110 and may provide vacuum, i.e., negative pressure, to vacuum nozzle 206 via flow resistor 502. Pressure tubes 136, 134 and 132 may connect to pressure ports 112, 114 and 116, respectively. Pressurized air or gas may pass through vertical holes in cover plate 108 and nozzle plate 106 and through horizontal passages in nozzle plate 106 to pressure nozzles 204 through flow resistors 502. Vacuum nozzles 206 are surrounded by vacuum segments 302 (see FIG. 3) and may keep a workpiece attached to the bottom of the chuck body 102 during processing, without touching the chuck body 102.

In some embodiments of the current invention, the flow resistors 502 may be different for different sets of pressure ports in the chuck. Each annular strip may include flow resistors 502 which are substantially uniform within the annular strip, and substantially different from the flow resistors 502 in another annular strip. The flow resistors 502 in the vacuum ring 104 may be substantially different from the flow resistors 502 in any of the annular strips.

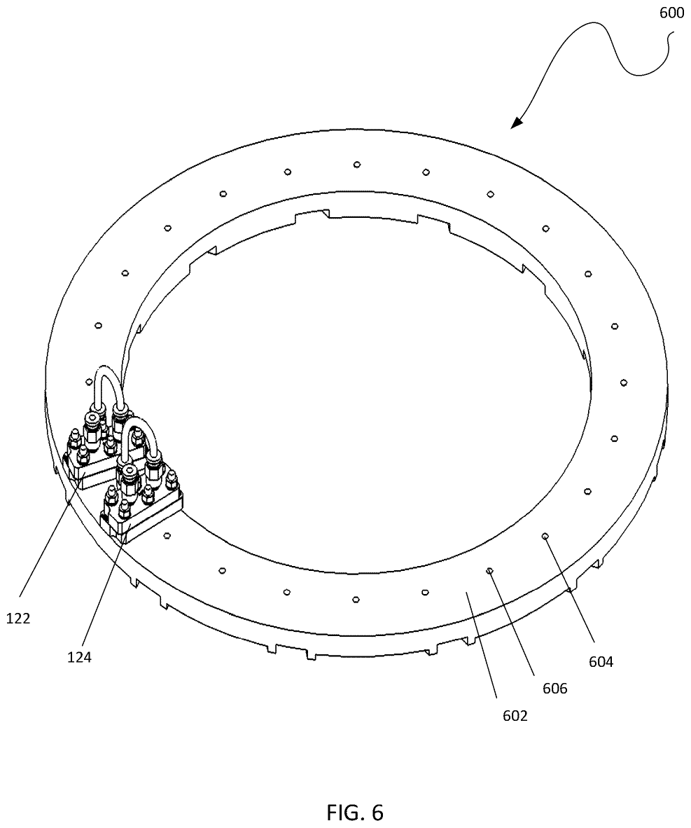

FIG. 6 is an oblique view of the top of a chuck ring for cooperation with a configurable chuck, according to some embodiments of the invention. Chuck ring may be used to remove excess material outward of a chuck during processing. Chuck ring 600 may be installed around chuck 100 or any chuck that may be fitted inside chuck ring 600. Fitting of chuck ring 600 around chuck 100 may be by way of additional parts (not shown). Chuck ring 600 may be configured to be attached to chuck 100 so as to rotate at the same rotational speed as chuck 100. Chuck ring 600 may remove excess abrasive material outward from chuck 100 during processing, by providing pressurized air through pressure nozzles distributed around chuck ring 600. The combination of pressurized air and rotation-induced centrifugal force may remove excess material outward of chuck 100. Flow restrictors 122 and 124 in assembly 600 may be installed around chuck ring body 602 and may provide pressurized air or gas to pressure nozzles 604 and 606 located around in chuck ring body 602 (only two of flow restrictors are shown for brevity). Pressurized air or gas and excess material may evacuate through gaps at the bottom of chuck ring 602 during processing.

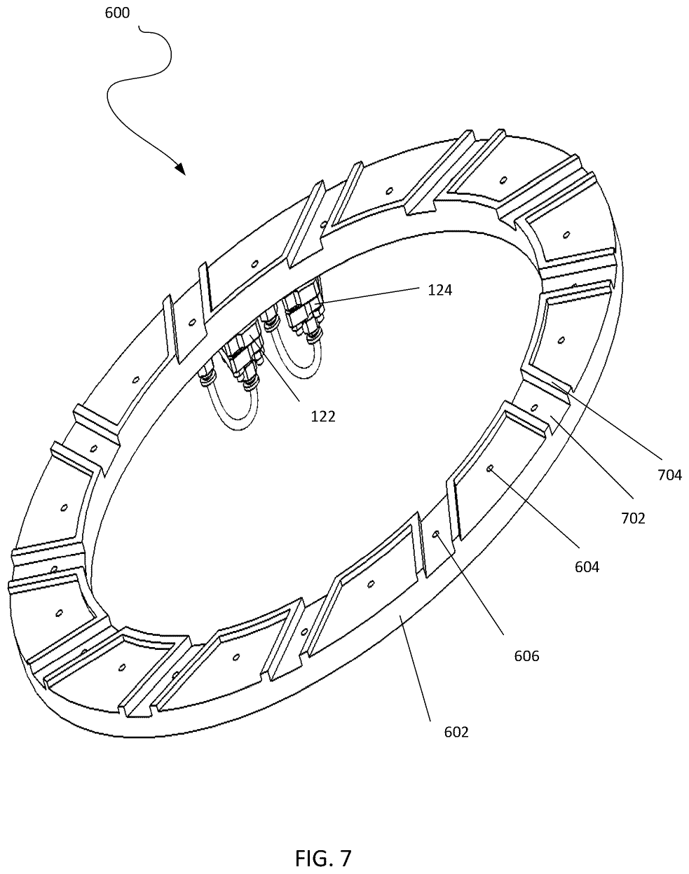

FIG. 7 is an oblique bottom view of the chuck ring of FIG. 6, according to some embodiments of the invention. Chuck ring 600 may include chuck ring body 602 and flow restrictors 122 and 124 (only two are shown). Chuck ring body 602 may include recess segments with raised rims 704. Pressure nozzles 604 may be located in chuck ring body 602 and may be surrounded on three sides by recess segments 704. Recess segments 704 may bind excess material on a workpiece and force it to exit outward of the chuck ring. Pressure nozzles 606 may be located in chuck ring body 602 in between recess segments 704. Pressurized air coming out of pressure nozzles 606 may be evacuated together with excess material through the gaps between recess segments 702. Pre-set flow restrictor 122 may control the pressure of pressure nozzles 606.

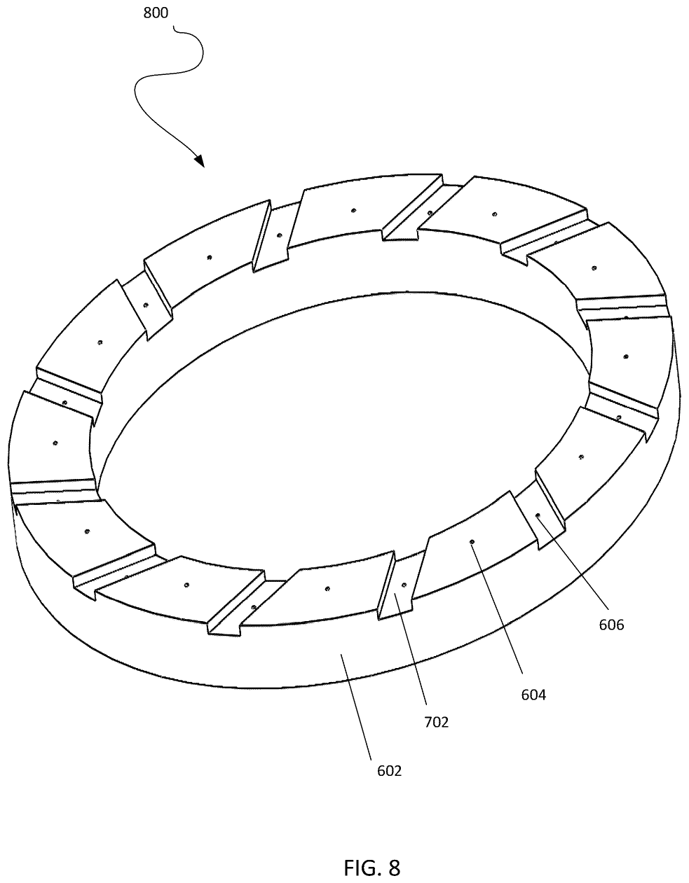

FIG. 8 shows an alternative design for the bottom of a chuck ring, for cooperation with a configurable chuck, according to some embodiments of the invention. Chuck ring 800 may include chuck ring body 602 with pressure nozzles 604 and 606. Pressurized air may be evacuated together with excess material outward of the chuck ring through gaps 702 in chuck ring body 602.

FIG. 9 is an oblique view of a configurable chuck and a chuck ring, according to some embodiments of the invention. Assembly 900 may include chuck body 102 and chuck ring body 602. Pre-set flow restrictors 122 (only one is shown) may be fluidically linked to pressure ports 904 which may be connected to pressure nozzles 606 (see FIG. 6) at the bottom surface of chuck ring body 602. Pre-set flow restrictors 124 (only one is shown) may be fluidically linked to pressure ports 902 which may provide pressurized air to pressure nozzles 604 (see FIG. 6) at the bottom surface of chuck ring body 602.

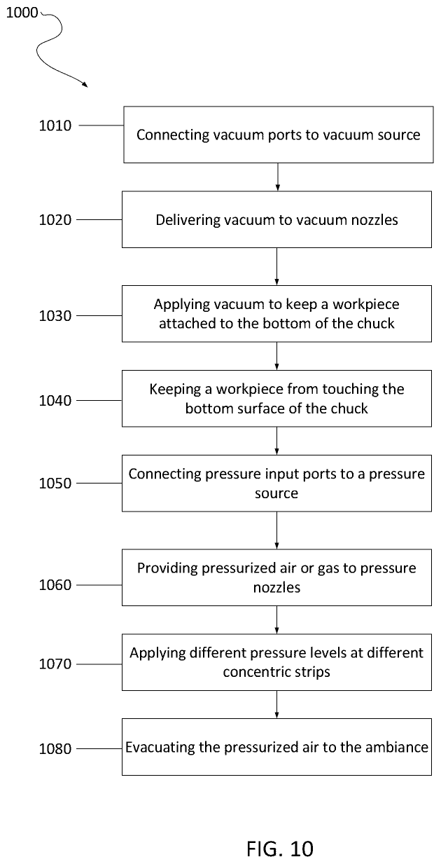

FIG. 10 is a flowchart description of a method for chemical and mechanical planarization processing, according to some embodiments of the invention. The methods of FIG. 10 may be used with example devices shown elsewhere herein, but may also be used with other suitable devices. Flow 1000 may start in block 1010, where the vacuum ports of a chuck (e.g., chuck 110 or another suitable chuck) may be connected to a vacuum source. In block 1020, vacuum may be delivered to vacuum nozzles (e.g., nozzles 206). In block 1030, a vacuum may be applied to keep a workpiece attached to the bottom of the chuck by the vacuum forces of the vacuum nozzles. In block 1040, a vacuum ring or vacuum segment rings may keep a workpiece from touching the bottom of a chuck. In block 1050, pressure input ports (e.g. ports 112, 114, 118 and 150) may be connected to a pressure source. In block 1060, air or pressurized gas may be provided to the pressure nozzles (e.g., nozzles 204 (a, b and c)). In block 1070, different pressure levels may be applied at different concentric strips. In block 1080, pressurized air or gas is evacuated to the ambiance through evacuation channels in a chuck body and to evacuation outlets in a top cover plate.

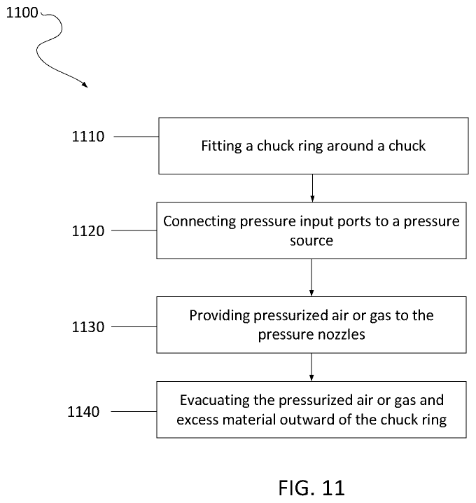

FIG. 11 is a flow chart description of a method for removal of excess material outward of a chuck, according to some embodiments of the invention. Flow 1100 may start in block 1110, where a chuck ring may be fitted snugly around a chuck. In block 1120, pressure inputs ports (e.g., 902 and 904) may be connected to a pressure source. In block 1130, pressurized air or gas may be provided to pressure nozzles. In block 1140, pressurized air or gas and excess material may be evacuated outward from a chuck ring, through gaps in a chuck ring body.

The aforementioned figures illustrate the architecture, functionality, and operation of possible implementations of systems and apparatus according to various embodiments of the present invention. Where referred to in the above description, an embodiment is an example or implementation of the invention. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions. It will further be recognized that the aspects of the invention described hereinabove (e.g. in different embodiments) may be combined or otherwise coexist in embodiments of the invention.

It is to be understood that the terms “including”, “comprising”, “consisting” and grammatical variants thereof do not preclude the addition of one or more components, features, steps, or integers or groups thereof and that the terms are to be construed as specifying components, features, steps or integers.

The descriptions, examples and materials presented in the claims and the specification are not to be construed as limiting but rather as illustrative only.

While the invention has been described with respect to a limited number of embodiments, these should not be construed as limitations on the scope of the invention, but rather as exemplifications of some of the preferred embodiments. Other or equivalent variations, modifications, and applications are also within the scope of the invention. Accordingly, the scope of the invention should not be limited by what has thus far been described, but by the appended claims and their legal equivalents.

1. A chuck for chemical and mechanical planarization processing, the chuck comprising:
a body comprising:
a substantially flat bottom surface having a plurality of pressure nozzles distributed across the bottom surface;
one or more pressure input ports for connecting to a pressure source, for providing a pressurized air or gas; and
internal passages, configured to deliver the pressurized air or gas to the plurality of pressure nozzles, and to apply pressure through the plurality of pressure nozzles onto a workpiece in a concentric manner,
wherein different pressure levels are obtained at different concentric strips of the plurality of pressure nozzles.

2. The chuck according to claim 1, wherein the body further comprises:
one or more vacuum input ports for connecting to a vacuum source;
a plurality of vacuum nozzles at the bottom of the chuck, along a concentric circle surrounding the pressure nozzles; and
internal passages, configured to deliver the vacuum to the plurality of vacuum nozzles, and to apply vacuum through the plurality of vacuum nozzles on a workpiece to keep a workpiece attached to the bottom of the chuck during processing.

3. The chuck according to claim 2, further comprising a plurality of evacuation channels in the chuck body for the pressurized air or gas.

4. The chuck according to claim 3, further comprising a concentric vacuum ring surrounding the plurality of vacuum nozzles and configured to keep a distance between the bottom of the chuck and a workpiece.

5. The chuck according to claim 2, further comprising a plurality of segmented vacuum rings surrounding the plurality of vacuum nozzles and configured to keep a distance between the bottom of the chuck and a workpiece and to allow evacuation of pressurized air or gas outward of the chuck in between the plurality of segmented vacuum rings.

6. The chuck according to claim 1, wherein the chuck body is substantially round.

7. The chuck according to claim 1, wherein one or more of the pressure input ports are connected to a pressure source via a preset, manually, or automatically controlled flow restrictor.

8. The chuck according to claim 1, wherein two or more of the pressure input ports are connected to a pressure source via a manually or automatically controlled common pressure valve.

9. The chuck according to claim 1, wherein one or more of the pressure input ports are connected to a pressure source via a pressure regulator.

10. The chuck according to claim 1, further comprising one or more pressure sensors, configured to measure the pressure of the one or more pressure input ports.

11. The chuck according to claim 1, further comprising one or more distance sensors, configured to measure the distance between the bottom of the chuck and the top of a workpiece and the thickness of a workpiece.

12. A chuck ring for removing excess material outward of a chuck during processing, the chuck ring comprising:
a ring with internal diameter configured to fit around a chuck;
a plurality of pressure nozzles distributed around the chuck ring;
a plurality of pressure input ports for connecting to a pressure source, for providing a pressurized gas to the plurality of pressure nozzles;
a plurality of flow restrictors on top of the chuck ring, each connected to a pressure source and to one of the plurality of pressure input ports; and
a plurality of channels at the bottom of chuck ring for evacuating pressurized air or gas and excess material outward from the chuck ring.

13. A method for chemical and mechanical planarization processing, the method comprising:
connecting one or more vacuum input ports of a chuck to a vacuum source, for providing vacuum to the chuck;
delivering vacuum through internal passages of the chuck to a plurality of vacuum nozzles at the bottom of the chuck along a concentric circle surrounding a plurality of pressure nozzles distributed across the bottom surface of the chuck;
applying vacuum through the plurality of vacuum nozzles on a workpiece to keep a workpiece attached to the bottom of the chuck during processing;
keeping a workpiece from touching the bottom surface of the chuck by a vacuum ring surrounding the plurality of vacuum nozzles;
connecting one or more pressure input ports of the chuck to a pressure source, for providing a pressurized air or gas to the chuck;
providing the pressurized air or gas through internal passages of the chuck to the plurality of pressure nozzles; and
applying different flow rates at different concentric strips of the plurality of pressure nozzles;
evacuating the pressurized air or gas through a plurality of evacuation channels in the body of the chuck.

14. The method according to claim 13, wherein keeping a workpiece from touching the bottom surface of the chuck is by a plurality of segmented vacuum rings surrounding the plurality of vacuum nozzles.

15. The method according to claim 14, wherein evacuating the pressurized air or gas is through a plurality of channels between the plurality of segmented vacuum rings.

16. The method according to claim 15, further comprising connecting one or more of the pressure input ports of the chuck to a pressure source via a manually or automatically controlled flow restrictor.

17. The method according to claim 16, further comprising connecting two or more of the pressure input ports of the chuck to a pressure source via a manually or automatically controlled common pressure valve.

18. The method according to claim 17, further comprising connecting one or more of the pressure input ports of the chuck to a pressure source via a pressure regulator.

19. The method according to claim 18, further comprising measuring the pressure of one or more of the pressure input ports of the chuck via a pressure sensor on the top of the chuck.

20. The method according to claim 18 further comprising measuring the distance between the bottom surface of the chuck and the top of a workpiece and the thickness of a workpiece, via distance sensors on top of the chuck.

21. A method for removing excess material outward of a chuck during processing, the method comprising:
fitting a chuck ring around a chuck;
connecting a plurality of pressure input ports of the chuck ring to a pressure source for providing a pressurized air or gas to the chuck ring;
providing the pressurized air or gas to a plurality of pressure nozzles distributed around the chuck ring; and
evacuating the pressurized air or gas and excess material outward of the chuck ring through a plurality of channels in the bottom surface of the chuck ring.
